(19) United States
(12) Patent Application Publication
(10) Pub. No.: US 2004/0042183 A1
(43) Pub. Date: Mar. 4, 2004

(54) Flex circuit package

(76) Inventors: Vicente D. Alcaria, Manteca, CA (US); Stanford W. Crane JR., San Jose, CA (US)

Correspondence Address: MCKENNA LONG & ALDRIDGE LLP, Song K. Jung, 1900 K Street, N.W., Washington, DC, 20006, US

(21) Appl. No.: 10/233,624

(22) Filed: Sep. 4, 2002

(51) Int. Cl. H05K 5/00; H05K 5/04; H05K 5/06

(52) U.S. Cl. 361/752

(57) ABSTRACT

A device package having flexible leads on a flex circuit that is insert molded into a housing. The device package includes a die attach area within the housing. The flexible leads include external ends for connecting to an external circuit and internal ends for wire bonding to a device die on the die attach area. The housing includes walls that surround the die attach area such that a device die on the die attach area can be sealed with an encapsulant. The device package is beneficially implemented in a handling frame having frame members with break tabs that are insert molded to the device package. The break tabs enable easy separation of a device package from the handling frame. The handling frames are beneficially formed into an assembly chain.

### CROSS-REFERENCE TO RELATED APPLICATIONS

Not applicable.

### BACKGROUND OF THE INVENTION

1. Field of the Invention

The present invention relates generally to semiconductor packaging and electrical interconnections. More specifically, the present invention relates to semiconductor packages having flexible connectors.

2. Discussion of the Related Art

Modern electronic systems make wide use of semiconductor chips that are packaged as electrical components. The semiconductor chips themselves typically contain microcircuits that perform predetermined electrical functions. Such microcircuits must interconnect with other system components. This is usually done by placing semiconductor chips in device packages that include conductive leads (pins) that extend through the package to enable external connections, such as by soldering to conductive paths on printed circuit boards. Bonding wires, solder balls, or other types of electrical connections then connect pads on the semiconductor chip to interior portions of the conductive leads. This general arrangement enables electrical signals to pass between the semiconductor chip and external structures.

Because semiconductor chips tend to be fragile, device packages are usually sealed, encased in plastic, and/or otherwise protected from the environment or damage from chemical, electrical, or mechanical influences.

The general arrangement of a housing having conductive leads for electrically interconnecting a semiconductor device with external structures is referred to hereinafter as a semiconductor package. Semiconductor packaging can include mounting plates for receiving a semiconductive device, a lid to seal the housing, potting compounds, and other features.

While device packages have been highly successful, advances in semiconductor technology and their uses have caused challenges to package designers. For example, as the number of semiconductor chip pads that must be electrically connected to conductive leads has increased, the difficulty of forming packages with the required number of conductive leads has grown. Complicating the matter is that size of the semiconductor chip and its device package must be kept small to increase achievable system speed, functionality, and performance. Thus, device packages having high-density leads are often required, which make the required interconnections and device package fabrication difficult to implement.

By definition, high-density leads are closely spaced, thus taking up less area and resulting in shorter signal paths than lower-density leads. The shorter signals paths can often enable electrical signals to pass at higher speeds. In general, when proper care is taken the higher the lead density, the better the achievable performance. However, there is a practical limit to the maximum lead density. That limit relates to the minimum separation between adjacent conductive leads that provides acceptable lead isolation and device package sealing. Additionally, as lead density increases it becomes more difficult to properly align the conductive leads with external features, such as printed circuit board connection pads.

On method of increasing the lead density is to arrange the leads into stacked rows of leads, with each row passing through a device package at different distances from the bottom of the device package. In practice, implementing device packages with leads closer than about 0.5 mm between adjacent leads is extremely difficult. Reasons for this include the difficulty of physically locating pins closer than 0.5 mm, the difficult of handling pins that are small enough to be located closer than 0.5 mm, the difficulty of sealing individual pins as they pass through a housing, maintaining lead integrity, and the difficult of solder (or otherwise connecting) the required electrical contacts to the individual pins within the device package. Arranging the leads in stacked rows often complicates the handling problems.

In addition to the foregoing problems, some applications (such as the application discussed in the “Detailed Description of an Illustrated Embodiment) would benefit from flexible conductive leads. In practice, implementing device packages with a high density of flexible leads is difficult to do, at least because flexible pins tend to electrically short. But, flexible conductors, such as those on flex-boards, are well known. Flex-boards are comprised of conductive patterns that are sandwiched between layers of tough, insulating film. Unfortunately, flex-boards have not been well suited for use as device package leads. Problems of note include sealing, interior contact preparation, and external contact formation.

Despite their prior limitations as device package leads, flex-boards have significant advantages. For example, flex-boards having high-density conductive traces are easy to produce since the conductive traces can be formed using lithography and etching. Another advantage is that the conductive trace dimensions, locations, and spacings are well defined, again because of the fabrication processes that are used. Still another advantage is that the tough, insulating film over the conductive traces protects those traces against shorts, environmental damage and physical shocks. Interestingly, the insulating film can be selectively applied to the flex-board using an adhesive.

In view of the limitations of the prior art, a new, high-density device package that can transmit signals to another location would be beneficial. Even more beneficial would be a new, high-density device package having flexible leads. Still more beneficial would be a new, high-density device package that uses conductors on a flex-board as leads. Particularly beneficial would be a new low cost, easy used, sealable, high-density device package having flexible leads.

### SUMMARY OF THE INVENTION

The following summary of the invention is provided to facilitate an understanding of some of the innovative features unique to the present invention, and is not intended to be a full description. A full appreciation of the various aspects of the invention can be gained by taking the entire specification, claims, drawings, and abstract as a whole.

The principles of the present invention provide for a new, device package that is suitable for applications that benefit from high-density flexible leads while minimizing the number of electrical interfaces. A device package that is in accord with the principles of the present invention includes a flex circuit having a plurality of conductive traces and a die attach area. The flex circuit beneficially is either insert molded into a plastic body, or inserted and then sealed, such that external ends of the conductive traces can be connected to external circuit and such that internal ends of the conductive traces can be connected to a device die on the die attach area. Beneficially, the plastic body includes walls that surround the die attach area such that a device die on the die attach area can be sealed with an encapsulant.

The principles of the present invention further provide that the device packages can be implemented in a handling frame comprised of a plurality of device packages that are interconnected by a strip frame. That frame includes break tabs, alignment holes, and/or sprocket openings. The handling frame enables the device packages to be used at high speed in an automated system wherein semiconductor or device dies are packaged into the device packages. The handling frame enables further automation of the installation of packaged devices into upper level assemblies.

The novel features of the present invention will become apparent to those of skill in the art upon examination of the following detailed description of the invention or can be learned by practice of the present invention. It should be understood, however, that the detailed description of the invention and the specific examples presented, while indicating certain embodiments of the present invention, are provided for illustration purposes only because various changes and modifications within the spirit and scope of the invention will become apparent to those of skill in the art from the detailed description of the invention and claims that follow.

### BRIEF DESCRIPTION OF THE DRAWING

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

In the drawings:

FIG. 1 illustrates a device package that is in accord with the principles of the present invention;

FIG. 2 illustrates a flex circuit board used in the device package illustrated in FIG. 1;

FIG. 3 illustrates the device package illustrated in FIG. 1 as part of a strip frame; and

FIG. 4 illustrates the strip frame of FIG. 3 in a handling frame.

### DETAILED DESCRIPTION OF THE ILUSTRATED EMBODIMENTS

Reference will now be made in detail to illustrated embodiments of the present invention. While the illustrated embodiments provide for useful device packages having high-density flexible leads, those illustrated embodiments are simply examples of device packages that incorporate the principles of the present invention.

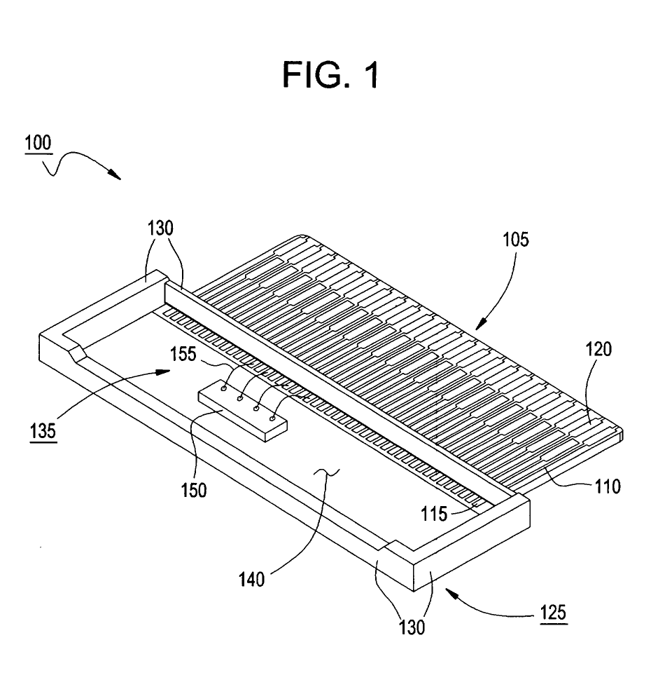

FIG. 1 illustrates a device package 100 that is in accord with the principles of the present invention. The device package 100 includes a flex circuit 105 with a plurality of conductive traces 110. The conductive traces 110 terminate inside the device package 100 in inner pads 115 and outside of the device package 100 in outer pads 120. The device package 100 further includes a plastic body 125 having walls 130 that form a cavity 135. The plastic body 125 is beneficially comprised of a liquid crystal polymer. Still referring to FIG. 1, the flex circuit 105 is beneficially insert molded into the plastic body 125.

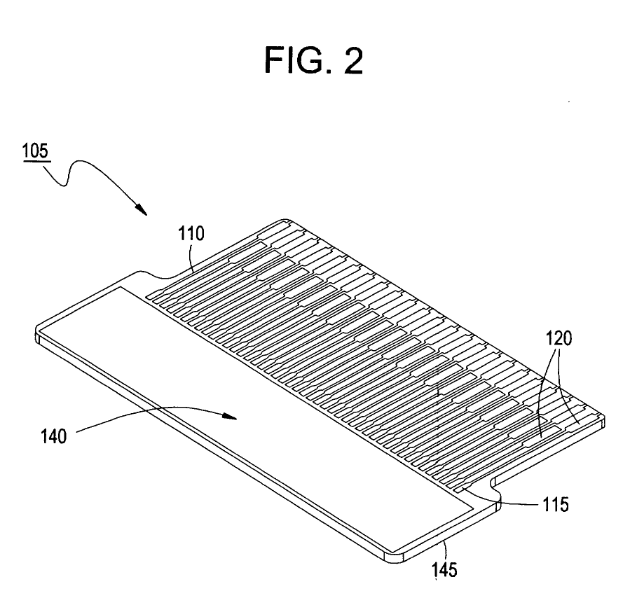

FIG. 2 illustrates the flex circuit 105 in more detail. As shown, the outer pads 120 terminate in two rows. This reduces the linear distance required for the outer pads 120, which enables a higher density of conductive traces 110, while retaining sufficient pad size to connect to an external connector (which is not shown). However, the inner pads 115 align along one row. Thus, the size of the inner pads 115 is less than that of the outer pads 120. However, as the inner pads 115 are subsequently connected to a device die using point-to-point wiring made by automated equipment, the small size of the inner pads 115 is acceptable.

Still referring to FIG. 2, the flex circuit 105 includes a die attach area 140. The die attach area 140 is dimensioned to receive one or more device dies. The flex circuit 105 beneficially includes a flexible board 145 comprised of a tough, flexible material that readily accepts adhesive. To fabricate the flex circuit 105, a copper coating is located on the flexible board 145. Then, using lithographic techniques, a resist pattern is formed on the copper coating. That resist pattern defines the inner pads 115, outer pads 120, conductive traces 110, and the die attach area 140. Then, the copper coating is etched, leaving copper at inner pads 115, outer pads 120, conductive traces 110, and the die attach area 140. If required, protective plating can be applied to the remaining copper. Furthermore, an optional protective film can be located over the conductive traces 110. Gold over nickel is an example of such an optional protective film. While the various features are described above as being metallic, this is not required. Other materials, specifically including an insulating plastic, can also be used.

Referring once again to FIG. 1, a process of packaging a device die will be described. First, a die attach material, beneficially an epoxy, is locating on the die attach area 140. Then, one or more device dies 150 are placed on the die attach material. The die attach material is then cured. A wire bonding process is then performed to connect inner pads 115 to the device die 150 using bonding wires 155. A dam and fill process is then performed. First, a dam material is placed and filled to form a protective layer over the bonding wires 155. The dam material is beneficially a plastic encapsulant, but other suitable insulting materials may be used. The fill material is then poured over the dam area. The walls 130 retain the material. The fill material is then cured. The fill material may be the same material as the same material, but with much lower viscosity.

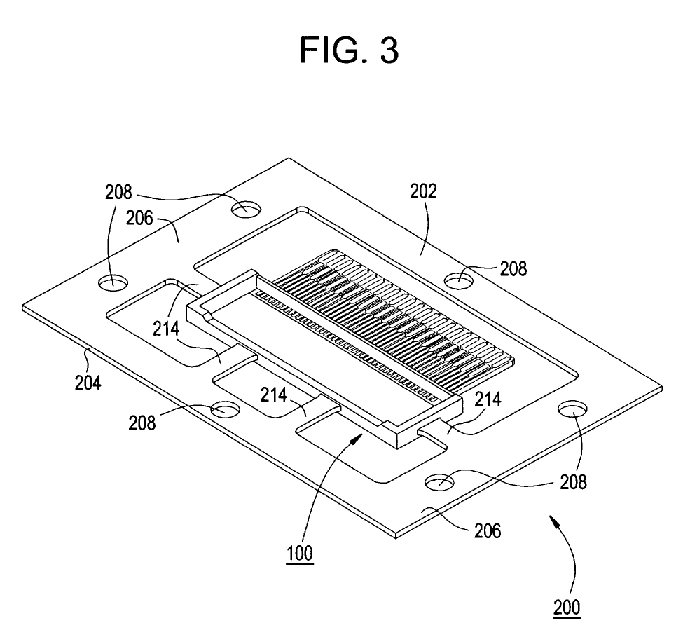

While the device package 100 by itself is highly useful, in practice the device package is beneficially formed with a handling frame. Such a structure is illustrated in FIG. 3. The handling frame 200 is beneficially an integral metallic structure comprised of a first frame member 202, a parallel second frame member 204, and end members 206 that connect the first and second frame members 202 and 204. The end members beneficially include two alignment holes 208, while the first and second frame members 202 and 204 each beneficially include one alignment hole 208.

Still referring to FIG. 3, the handling frame 200 further includes four break tabs 214. Two of the break tabs extend from the second frame member 204 to the device package 100 and each end member 206 includes one break tab 214 that extends to the device package 100. It should be understood that the break tabs 214 are insert molded into the housing 125 (see FIG. 1). The break tabs 214 are just that, they break away from the housing 125 under an applied pressure. This enables the device package 100 to be separated from the handling frame 200. The tabs 214 can have reduced cross sections in the area where separation is desired. While the various features of the handling frame are described above as being metallic, this is not required. Other materials, specifically including tape, mylar, other insulating plastics, or other flexible or semiflexible materials can also be used.

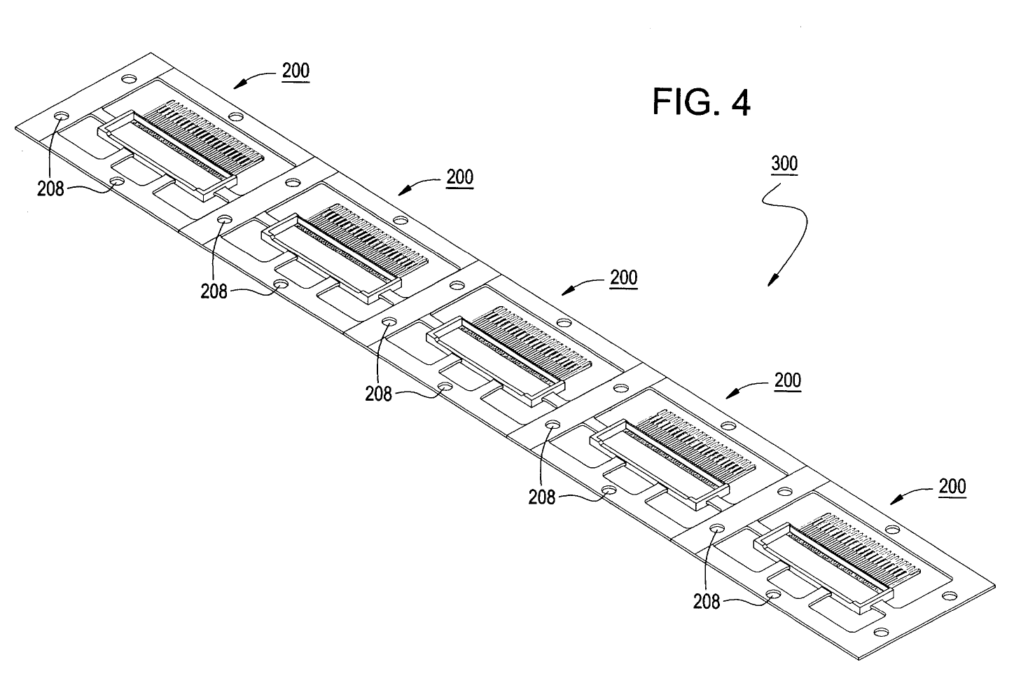

Referring now to FIG. 4, the handling frame 200 is beneficially part of an assembly chain 300. That chain includes a plurality of connected handling frames 200. That assembly chain 300 is highly beneficial in that it enables high-speed, automated assembly and alignment of the device packages 100. The alignment holes 208 can engage with a sprocketed automated assembly machine. That assembly machine can then advance each device package 100 to an assembly station where a device die is packaged within each device package 100. Then, the assembly chain 300 enables the assembled device package to be wrapped into a spool, shipped, handled, and then inserted onto a printed circuit board or other upper level assembly.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the spirit and scope of the following claims. It is contemplated that the use of the present invention can involve components having different characteristics. It is intended that the scope of the present invention be defined by the claims appended hereto, giving full cognizance to equivalents in all respects.

What is claimed is:

The embodiments of an invention in which an exclusive property or right is claimed are defined as follows:

1. A device package, comprising:
a housing having a plurality of walls that form an enclosed region; and
a flex circuit insert molded into said housing, said flex circuit including a plurality of flexible leads and a die attach area, wherein said die attach area is in said enclosed region, wherein said plurality of flexible leads extend from within said housing to outside said housing.

2. A device package according to claim 1, wherein said housing is a liquid crystal polymer.

3. A device package according to claim 1, wherein said die attach area includes a metallic base.

4. A device package according to claim 1, wherein said die attach area includes a flexible base.

5. A device package according to claim 1, wherein said plurality of flexible leads and said die attach area are formed on an insulating plastic.

6. A device package according to claim 1, further including a device die attached to said die attach area and at least one electrical connector connecting said device die to a first flexible lead of said plurality of flexible leads.

7. A device package according to claim 6, wherein said device die is encapsulated in said enclosed region.

8. A device package according to claim 7, wherein said encapsulation is performed using a dam and fill process.

9. A device assembly structure, comprising:
a housing having a plurality of walls that form an enclosed region;
a flex circuit insert molded into said housing, said flex circuit including a plurality of flexible leads and a die attach area, wherein said die attach area is within said enclosed region, and wherein said plurality of flexible leads extend from within said housing to outside said housing; and
a handling frame comprised of a first frame member, a second frame member, and end members that interconnect said first and second frame members together, wherein said handling frame includes at least one break tab that is insert molded into said housing.

10. A device package according to claim 9, wherein said die attach area includes a metallic base.

11. A device package according to claim 9, wherein said plurality of flexible leads and said die attach area are formed on an insulating plastic.

12. A device package according to claim 9, further including both a device die attached to said die attach area and at least one electrical conductor connecting said device die to a first flexible lead of said plurality of flexible leads.

13. A device package according to claim 12, wherein said device die is encapsulated in said enclosed region.

14. A device package according to claim 13, wherein said encapsulation is performed using a dam and fill process.

15. A device package according to claim 9, wherein said handling frame is flexible.

16. A device package according to claim 9, wherein said handling frame includes at least one alignment hole.

17. A device package according to claim 9, wherein said handling frame is part of a coil of handling frames.

18. A device assembly chain, comprising:
a plurality of interconnected packaging assemblies, each having:
a housing with a plurality of walls that form an enclosed region;
a flex circuit insert molded into said housing, said flex circuit including a plurality of flexible leads and a die attach area, wherein said die attach area is within said enclosed region, and wherein said plurality of flexible leads extend from within said housing to outside said housing; and
a handling frame comprised of a first frame member, a second frame member, and end members that interconnect said first and second frame members together, wherein said handling frame includes at least one break tab that is insert molded into said housing;
wherein said device assembly chain is formed by connecting end members together; and
wherein each handling frame includes at least one alignment hole on an outer portion.

19. A device package according to claim 18, further including both a device die attached to said die attach area and at least one electrical connector connecting said device die to a first flexible lead of said plurality of flexible leads.

20. A device package according to claim 19, wherein said device die is encapsulated in said enclosed region.

21. A device package according to claim 20, wherein said encapsulation is performed using a dam and fill process.

22. A device package according to claim 18, wherein said handling frame is flexible.
